(19) United States
(12) Patent Application Publication
(10) Pub. No.: US 2022/0336504 A1
(43) Pub. Date: Oct. 20, 2022

(54) SEMICONDUCTOR DEVICE AND METHOD FOR MANUFACTURING THE SAME, AND ELECTRONIC APPARATUS

(71) Applicant: SONY SEMICONDUCTOR SOLUTIONS CORPORATION, Kanagawa (JP)

(72) Inventor: Yoshiaki KITANO, Kanagawa (JP)

(73) Assignee: SONY SEMICONDUCTOR SOLUTIONS CORPORATION, Kanagawa (JP)

(21) Appl. No.: 17/760,744

(22) PCT Filed: Jul. 15, 2020
(86) PCT No.: PCT/JP2020/027548

§ 371 Date: Mar. 15, 2022

(30) Foreign Application Priority Data
Sep. 26, 2019 (JP) 2019-175189

(51) Int. Cl. H01L 27/146; H01L 23/00

(52) U.S. Cl. CPC H01L 27/1461; H01L 27/14643; H01L 27/14627; H01L 24/08; H01L 27/14634; H01L 27/1463; H01L 27/14636; H01L 27/14689; H01L 2224/08145

(57) ABSTRACT

A semiconductor device capable of reducing the size of pixels while maintaining a device withstand voltage is provided. The semiconductor device includes a pixel array unit in which a plurality of pixels each having an avalanche photodiode element is arranged in a matrix, and the avalanche photodiode element includes: a first electrode region of a first conductivity type and a second electrode region of a second conductivity type, the first electrode region and the second electrode region forming a p-n junction on the side of a first surface of a pixel formation region of a semiconductor layer, an avalanche multiplication region at the interface portion of the p-n junction; a contact region of the first conductivity type on the first surface side of the pixel formation region while being electrically connected to the first electrode region; and an insulating portion between the contact region and the second electrode region.

### TECHNICAL FIELD

The present technology (the technology according to the present disclosure) relates to a semiconductor device, a method for manufacturing the same, and an electronic apparatus, and more particularly, to a semiconductor device including avalanche photodiodes (APDs), a method for manufacturing the same, and a technology effective for application to an electronic apparatus.

### BACKGROUND ART

As semiconductor devices, distance image sensors (solid-state imaging devices) that perform distance measurement by a time-of-flight (ToF) method have been attracting attention these days. Such a distance image sensor includes a pixel array unit in which a plurality of pixels is arranged in a matrix. Further, the efficiency of the entire device is determined by the dimension of the pixels and the pixel structure.

Patent Document 1 discloses a pixel structure that uses APD elements as the photoelectric conversion elements included in the pixels. This pixel structure includes: a p-type first electrode region (p-type semiconductor region) and an n-type second electrode region (n-type semiconductor region) that are provided to form a p-n junction in an upper portion on a first surface side of a pixel formation region of a semiconductor layer, and have avalanche multiplication regions formed at the interface portion of the p-n junction; a charge storage region that is provided around the first electrode region and the second electrode region; and a p-type contact region that is provided in an upper portion of the pixel formation region so as to be electrically connected to the charge storage region. This pixel structure can reduce crosstalk, and lower the dark count rate (DCR) (dark current rate).

### CITATION LIST

### Patent Document

Patent Document 1: Japanese Patent Application Laid-Open No. 2018-201005

### SUMMARY OF THE INVENTION

### Problems to be Solved by the Invention

Meanwhile, there is a demand for a reduction in the size of distance image sensors, as the electronic apparatuses to be mounted in distance image sensors have been becoming smaller. In making distance image sensors smaller, miniaturization of pixels is effective.

However, in a lateral structure in which the p-type first electrode region and the n-type second electrode region forming a p-n junction, and the p-type contact region are provided in an upper portion of the pixel formation region as in the pixel structure disclosed in Patent Document 1, the n-type second electrode region and the p-type contact region come closer to each other as the pixel size becomes smaller, and it becomes difficult to maintain the withstand voltage (device withstand voltage) between the n-type second electrode region and the p-type contact region. Therefore, to reduce the pixel size, it is necessary to maintain the device withstand voltage, and there is room for improvement.

The present technology aims to provide a semiconductor device capable of reducing the pixel size while maintaining the device withstand voltage, a method for manufacturing the semiconductor device, and an electronic apparatus.

### Solutions to Problems

A semiconductor device according to one aspect of the present technology includes

a pixel array unit in which a plurality of pixels each having an avalanche photodiode element is arranged in a matrix,

the avalanche photodiode element including:

a first electrode region of a first conductivity type and a second electrode region of a second conductivity type, the first electrode region and the second electrode region being provided to form a p-n junction on the side of a first surface, the first surface and a second surface being located on the opposite sides of a pixel formation region of a semiconductor layer, an avalanche multiplication region being formed at the interface portion of the p-n junction;

a contact region of the first conductivity type that is provided on the first surface side of the pixel formation region of the semiconductor layer while being electrically connected to the first electrode region; and

an insulating portion that is provided between the contact region and the second electrode region.

A semiconductor device manufacturing method according to another aspect of the present technology includes:

the step of forming a first electrode region of a first conductivity type and a second electrode region of a second conductivity type forming a p-n junction with the upper side of the first electrode region, on a first surface side of a semiconductor layer;

the step of forming a contact region of the first conductivity type that is electrically connected to the first electrode region, on the first surface side of the semiconductor layer; and

the step of forming an insulating portion between the second electrode region and the contact region.

An electronic apparatus according to another aspect of the present technology includes: the above semiconductor device; and an optical system that forms an image of image light from the object on the second surface of the pixel formation region.

### BRIEF DESCRIPTION OF DRAWINGS

FIG. 1 is a chip layout diagram showing an example configuration of a distance image sensor according to a first embodiment of the present technology.

FIG. 2 is a block diagram showing an example configuration of the distance image sensor according to the first embodiment of the present technology.

FIG. 3 is an equivalent circuit diagram showing an example configuration of a pixel.

FIG. 4 is a plan view of a relevant portion, showing an example configuration of a pixel.

FIG. 5 is a cross-sectional view of the relevant portion, showing a cross-section structure taken along the section line II-II defined in FIG. 4.

FIG. 6 is an enlarged cross-sectional view of the relevant portion, showing a portion in FIG. 5 in an enlarged manner.

FIG. 7 is a process cross-sectional view illustrating a method for manufacturing the distance image sensor according to the first embodiment of the present technology.

FIG. 8 is a process cross-sectional view continuing from FIG. 7, illustrating the method for manufacturing the distance image sensor according to the first embodiment of the present technology.

FIG. 9 is a process cross-sectional view continuing from FIG. 8, illustrating the method for manufacturing the distance image sensor according to the first embodiment of the present technology.

FIG. 10 is a process cross-sectional view continuing from FIG. 9, illustrating the method for manufacturing the distance image sensor according to the first embodiment of the present technology.

FIG. 11 is a process cross-sectional view continuing from FIG. 10, illustrating the method for manufacturing the distance image sensor according to the first embodiment of the present technology.

FIG. 12 is a process cross-sectional view continuing from FIG. 11, illustrating the method for manufacturing the distance image sensor according to the first embodiment of the present technology.

FIG. 13 is a process cross-sectional view continuing from FIG. 12, illustrating the method for manufacturing the distance image sensor according to the first embodiment of the present technology.

FIG. 14 is a process cross-sectional view continuing from FIG. 13, illustrating the method for manufacturing the distance image sensor according to the first embodiment of the present technology.

FIG. 15 is a process cross-sectional view continuing from FIG. 14, illustrating the method for manufacturing the distance image sensor according to the first embodiment of the present technology.

FIG. 16 is a process cross-sectional view continuing from FIG. 15, illustrating the method for manufacturing the distance image sensor according to the first embodiment of the present technology.

FIG. 17 is a process cross-sectional view continuing from FIG. 16, illustrating the method for manufacturing the distance image sensor according to the first embodiment of the present technology.

FIG. 18 is a process cross-sectional view continuing from FIG. 17, illustrating the method for manufacturing the distance image sensor according to the first embodiment of the present technology.

FIG. 19 is a process cross-sectional view continuing from FIG. 18, illustrating the method for manufacturing the distance image sensor according to the first embodiment of the present technology.

FIG. 20 is a process cross-sectional view continuing from FIG. 19, illustrating the method for manufacturing the distance image sensor according to the first embodiment of the present technology.

FIG. 21 is a plan view of a first modification.

FIG. 22A is a plan view of a second modification.

FIG. 22B is a cross-sectional view showing a cross-section structure taken along the line III-III defined in FIG. 22A.

FIG. 23 is a plan view of a third modification.

FIG. 24 is a plan view of a fourth modification.

FIG. 25 is a cross-sectional view of a relevant portion, showing a configuration of a pixel of a distance image sensor according to a second embodiment of the present technology.

FIG. 26 is a block diagram showing an example configuration of a distance image device using a sensor chip of the present technology.

### MODES FOR CARRYING OUT THE INVENTION

The following is a description of embodiments of the present technology, with reference to the drawings. In the explanation of the drawing to be referred to in the description below, the same or similar components are denoted by the same or similar reference numerals. However, it should be noted that the drawings are schematic, and the relationship between thickness and planar dimension, the ratio of the thickness of each layer, and the like are different from actual ones. Therefore, specific thicknesses and dimensions should be determined, with the following description being taken into consideration. Further, it is needless to say that the dimensional relationships and ratios may differ between the drawings. Note that the advantageous effects described in this specification are merely examples, and the advantageous effects of the present technology are not limited to them or may include some other effects.

Further, in the following embodiments, of three directions orthogonal to one another in a space, a first direction and a second direction orthogonal to each other in the same plane are defined as the X direction and the Y direction, respectively, and a third direction orthogonal to the first direction and the second direction is defined as the Z direction.

Also, in this specification and the accompanying drawings, the majority carriers in a layer or a region denoted with “n” or “p” are electrons or holes, respectively.

### First Embodiment

In a first embodiment, an example in which the present technology is applied to a distance image sensor of a back-illuminated type as a semiconductor device is described.

<Configuration of a Distance Image Sensor>

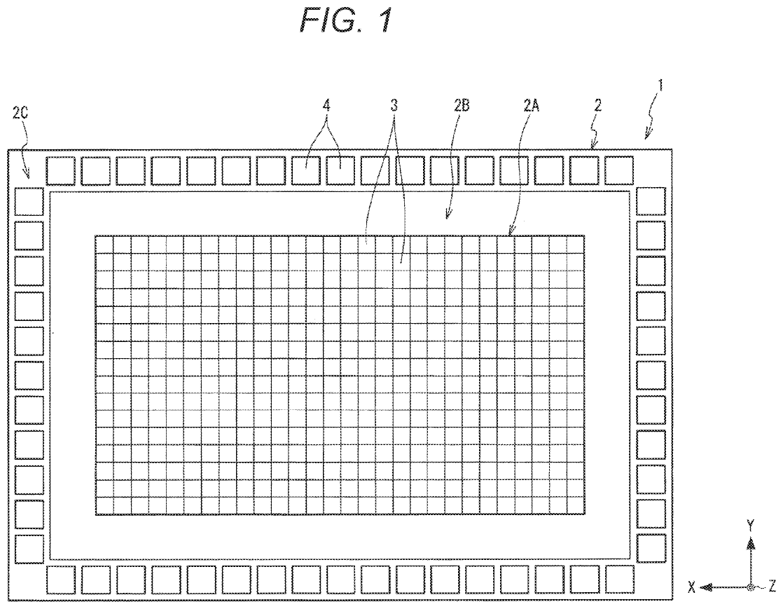

As shown in FIG. 1, a distance image sensor 1 according to the first embodiment of the present technology is formed primarily with a sensor chip 2 having a rectangular shape in a plan view. The sensor chip 2 includes a pixel array unit 2A disposed at the center of the rectangle, a peripheral region 2B disposed outside the pixel array unit 2A so as to surround the pixel array unit 2A, and a pad region 2C disposed outside the peripheral region 2B so as to surround the peripheral region 2B.

The pixel array unit 2A is a light receiving surface that receives light condensed by an optical system that is not shown in the drawings. Further, in the pixel array unit 2A, a plurality of pixels 3 is arranged in a matrix on a two-dimensional plane including the X direction and the Y direction.

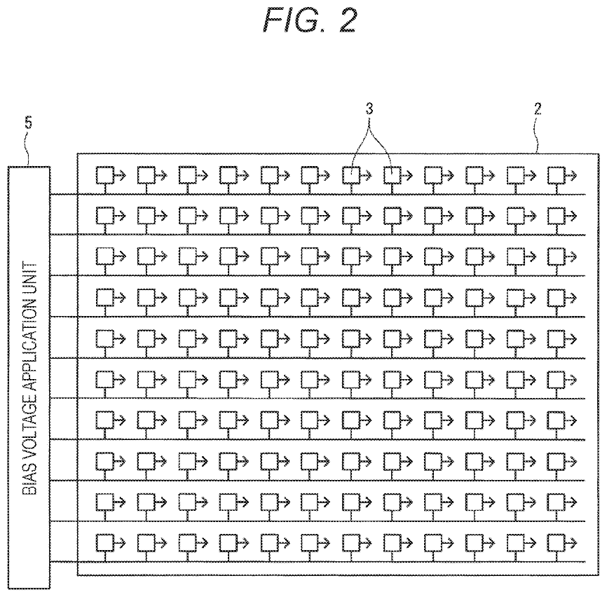

A bias voltage application unit 5 shown in FIG. 2 and other circuit units are disposed in the peripheral region 2B. The bias voltage application unit 5 applies a bias voltage to each pixel of the plurality of pixels 3 disposed in the pixel array unit 2A.

As shown in FIG. 1, in the pad region 2C, a plurality of electrode pads 4 is aligned along each side of the plane of the sensor chip 2. The electrode pads 4 are used for electrically connecting the sensor chip 2 to an external device that is not shown in the drawings.

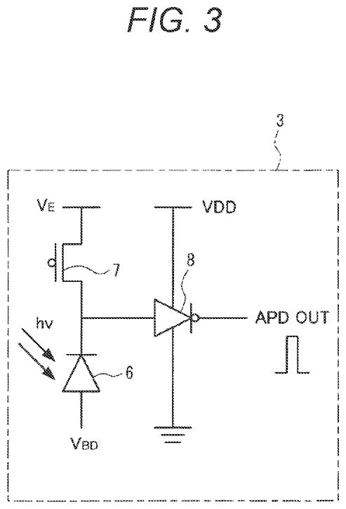

As shown in FIG. 3, a pixel 3 includes an avalanche photodiode (APD) element 6 as a photoelectric conversion element, for example, a quenching resistive element 7 formed with a p-type metal oxide semiconductor field effect transistor (MOSFET), for example, and an inverter 8 formed with a complementary MOSFET (complementary MOS), for example.

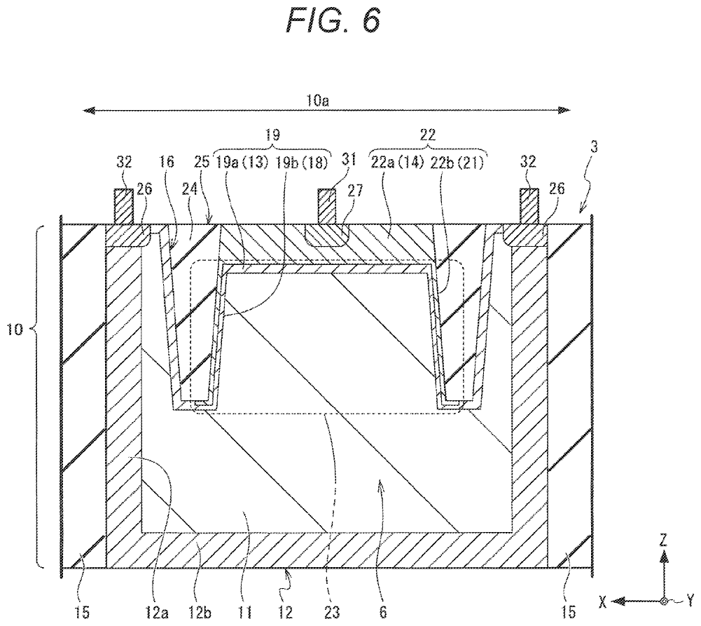

The APD element 6 has an anode connected to the bias voltage application unit 5 (see FIG. 2), and a cathode connected to the source terminal of the quenching resistive element 7. A bias voltage VB is applied from the bias voltage application unit 5 to the anode of the APD element 6. As a large negative voltage is applied to the cathode, the APD element 6 forms an avalanche multiplication region 23 (see FIG. 6), and can avalanche-multiply the electrons generated by incidence of one font.

The quenching resistive element 7 is connected in series to the APD element 6, the source terminal thereof being connected to the cathode of the APD element 6, the drain terminal thereof being connected to the power supply that is not shown in the drawings. An excitation voltage VE is applied from the power supply to the drain terminal of the quenching resistive element 7. When the voltage generated by the electrons avalanche-multiplied by the APD element 6 reaches a negative voltage VBD, the quenching resistive element 7 emits the electrons multiplied by the APD element 6, and performs quenching to return the voltage to the initial voltage. When the cathode voltage of the APD element 6 reaches the negative voltage VBD, the quenching resistive element 7 performs quenching by emitting the electrons multiplied by the APD element 6.

The inverter 8 has an input terminal connected to the cathode of the APD element 6 and the source terminal of the quenching resistive element 7, and an output terminal connected to an arithmetic processing unit in a later stage that is not shown in the drawings. The inverter 8 outputs a light reception signal, on the basis of the electrons multiplied by the APD element 6. More specifically, the inverter 8 shapes the voltage generated by the electrons multiplied by the APD element 6. The inverter 8 then outputs, to the arithmetic processing unit, a light reception signal (APD OUT) in which the pulse waveform shown in FIG. 3 is generated, for example, the arrival time of one font being the starting point. For example, the arithmetic processing unit performs arithmetic processing to determine the distance to the object, on the basis of the timing at which the pulse indicating the arrival time of one font is generated in each light reception signal. In this manner, a distance is determined for each pixel 3. Further, on the basis of these distances, a distance image in which the distances to the object detected by the plurality of pixels 3 are planarly arranged is generated.

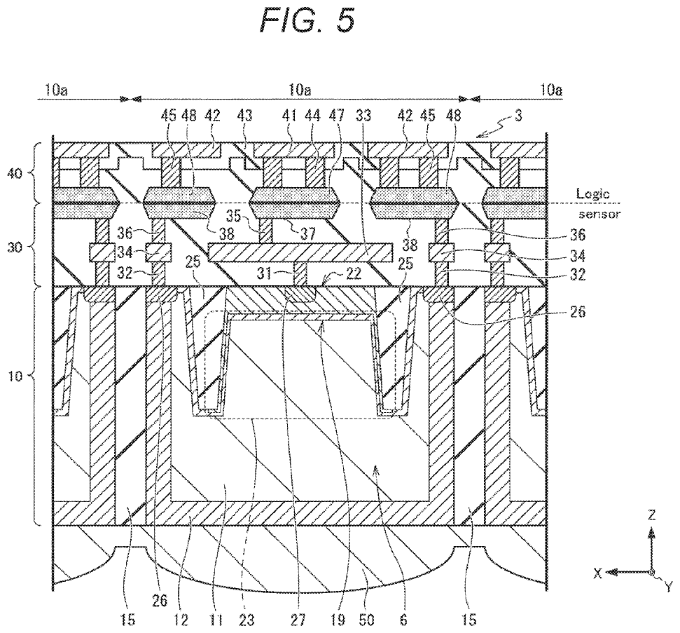

As shown in FIG. 5, the sensor chip 2 has a stack structure in which a sensor substrate 10 as a semiconductor layer, a sensor-side wiring layer 30, and a logic-side wiring layer 40 are stacked in this order. Further, a logic circuit board that is not shown in the drawings is stacked on the logic-side wiring layer 40.

On the logic circuit board, the bias voltage application unit 5, the quenching resistive element 7, the inverter 8, and the like shown in FIG. 2 are formed, for example. As shown in FIG. 5, the sensor substrate 10 and the logic circuit board are electrically connected by the sensor-side wiring layer 30 and the logic-side wiring layer 40, which are wiring layers. For example, the sensor chip 2 can be manufactured by a manufacturing method in which the sensor-side wiring layer 30 is provided to face the sensor substrate 10, the logic-side wiring layer 40 is provided to face the logic circuit board, and the sensor-side wiring layer 30 and the logic-side wiring layer 40 are then joined to each other in a bonding plane (the plane indicated by a dashed line in FIG. 5).

The sensor substrate 10 is formed with a semiconductor substrate containing single-crystal silicon, for example. In the sensor substrate 10, the concentration of an impurity exhibiting the p-type (a first conductivity type) or the n-type (a second conductivity type) is controlled, and an APD element 6 is formed in each pixel 3. Further, the surface of the sensor substrate 10 facing downward in FIG. 5 is the light receiving surface that receives light, and the sensor-side wiring layer 30 is stacked on the surface (the surface facing upward in FIG. 5) on the side opposite to the light receiving surface. On the light receiving surface of the sensor substrate 10, an on-chip lens 50 is provided for each pixel 3.

Here, the light receiving surface of the sensor substrate 10 is also referred to as the second surface or the light incident surface, and the surface on the side opposite to the light receiving surface is also referred to as the first surface or the back surface. Further, the second surface side of the sensor substrate 10 is also referred to as the upper portion, and the second surface side is also referred to as the lower portion.

In the sensor-side wiring layer 30 and the logic-side wiring layer 40, a wiring line for supplying the voltage to be applied from the bias voltage application unit 5 to the APD element 6, a wiring line for extracting the electrons generated in the APD element 6 from the sensor substrate 10, and the like are formed.

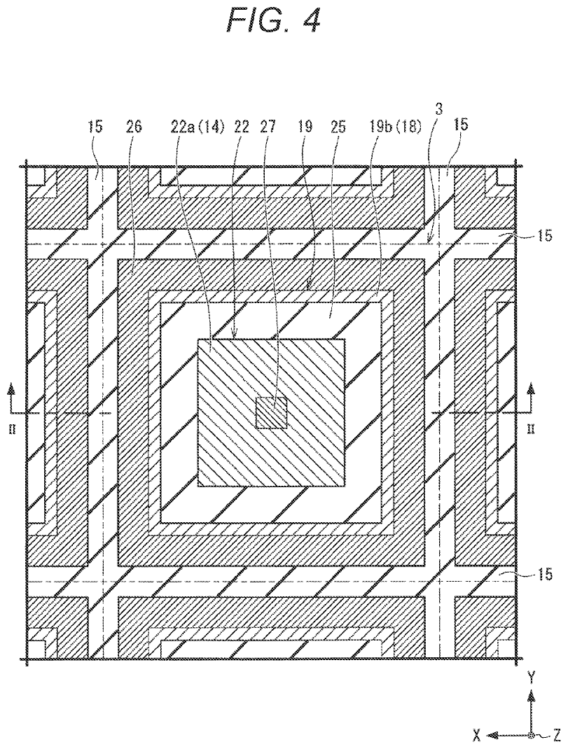

As shown in FIGS. 4 and 5, a pixel 3 includes a pixel formation region 10a of the sensor substrate 10, and an inter-pixel separation region 15 that defines the pixel formation region 10a. In the pixel formation region 10a, a planar pattern as viewed in a plan view in the direction toward the first surface (the surface on the side opposite to the light receiving surface) of the sensor substrate 10 is a square pattern. Further, a plurality of pixel formation regions 10a is aligned in both the X direction and the Y direction orthogonal to each other, with the inter-pixel separation region 15 being interposed in between.

The inter-pixel separation region 15 electrically separates the pixel formation regions 10a adjacent to each other. The inter-pixel separation region 15 has a shallow trench isolation (STI) structure, for example, and extends in the depth direction (the thickness direction) from the first surface (the principal surface) of the sensor substrate 10. The planar pattern of the inter-pixel separation region 15 corresponding to one pixel 3 as viewed in a plan view toward the first surface of the sensor substrate 10 is a lattice-like (mesh-like) planar pattern, as shown in FIG. 4. Further, although not specifically shown in the drawings, the planar pattern of the inter-pixel separation region 15 corresponding to the pixel array unit 2A is a composite planar pattern having a lattice-like planar pattern in a square annular planar pattern.

As described above, a pixel 3 includes an APD element 6. Further, as shown in FIGS. 5 and 6, the APD element 6 includes: an n-type (second conductivity type) well region 11 provided in the pixel formation region 10a of the sensor substrate 10; and a p-type (the first conductivity type) first electrode region 19 and an n-type second electrode region 22 that are provided to form a p-n junction in an upper portion (the first surface side) of the pixel formation region 10a of the sensor substrate 10, and have the avalanche multiplication region 23 formed in the interface portion of the p-n junction. The APD element 6 also includes: a p-type contact region 26 that is provided in an upper portion of the pixel formation region 10a of the sensor substrate 10 so as to be electrically connected to the p-type first electrode region 19; and an insulating portion 25 that is provided between the p-type contact region 26 and the n-type second electrode region 22. Further, the APD element 6 also includes: a p-type charge storage region 12 that is provided in the pixel formation region 10a of the sensor substrate 10 so as to be electrically connected to the p-type contact region 26; and an n-type contact region 27 that is provided in an upper portion of the n-type second electrode region 22. That is, the pixel 3 includes the APD element 6, and the insulating portion 25 provided between the n-type second electrode region 22 and the p-type contact region 26 of the APD element 6. The first electrode region 19, the n-type second electrode region 22, and the insulating portion 25 are provided in the n-type well region 11.

As shown in FIG. 6, the n-type well region 11 is provided to extend from the side of the first surface (the surface on the side opposite to the light receiving surface) to the side of the second surface (the light receiving surface) of the sensor substrate 10, and forms an electric field for transferring the electrons generated by photoelectric conversion performed by the APD element 6 to the avalanche multiplication region 23. Although the n-type well region 11 is used in the first embodiment, a p-type well region may be used, instead of the n-type well region 11.

As shown in FIG. 6, the insulating portion 25 extends in the thickness direction (Z direction) of the pixel formation region 10a of the sensor substrate 10. Further, the p-type first electrode region 19 and the n-type second electrode region 22 forming the p-n junction include: first portions 19a and 22a in which the n-type second electrode region 22 and the p-type first electrode region 19 are aligned in this order in the direction from the first surface side of the pixel formation region 10a of the sensor substrate 10 toward the second surface side on the opposite side (or in the depth direction (Z direction) from the upper surface); and second portions 19b and 22b that extend along the insulating portion 25 from the first portions 19a and 22a. That is, as for the first portion 19a of the p-type first electrode region 19 and the first portion 22a of the n-type second electrode region 22, the first portion 22a and the first portion 19a are arranged in this order from the first surface side toward the second surface side on the opposite side in the thickness direction of the pixel formation region 10a. Also, as for the second portion 19b of the p-type first electrode region 19 and the second portion 22b of the n-type second electrode region 22, the second portion 22b and the second portion 19b are arranged in this order from the side of the insulating portion 25 toward the side of the n-type contact region 27 in the planar direction of the pixel formation region 10a.

The second portion 19b of the p-type first electrode region 19 reaches the p-type contact region from the first portion 19a beyond the lower portion side opposite to the first surface side of the pixel formation region 10a of the insulating portion 25, and is electrically and mechanically connected to the p-type contact region. On the other hand, the second portion 22b of the n-type second electrode region 22 terminates immediately below the insulating portion 25.

As shown in FIG. 6, the first portion 22a of the n-type second electrode region 22 is p-n joined to the first portion 19a of the first electrode region 19 on the upper side of the first portion 19a of the p-type first electrode region 19. The second portion 22b of the n-type second electrode region 22 is p-n joined to the second portion 19b of the first electrode region 19 on the upper side of the second portion 19b of the p-type first electrode region 19.

As shown in FIG. 6, in the p-type first electrode region 19, the first portion 19a is formed with a p-type semiconductor region 13 (a first semiconductor region), and the second portion 19b is formed with a p-type semiconductor region 18 (a third semiconductor region). The semiconductor regions 13 and 18 have substantially the same impurity concentration, and further, each have a substantially uniform thickness.

In the n-type second electrode region 22, the first portion 22a is formed with an n-type semiconductor region 14 (a second semiconductor region), and the second portion 22b is formed with an n-type semiconductor region 21 (a fourth semiconductor region). The semiconductor regions 14 and 21 have substantially the same impurity concentration, and further, each have a substantially uniform thickness.

As shown in FIG. 6, the avalanche multiplication region 23 is a high-field region (a depletion layer) formed at the interface portion of the p-n junction between the p-type first electrode region 19 and the n-type second electrode region 22 by a large negative voltage applied to the p-type contact region 26, and multiplies the electrons (e−) generated by one font entering the APD element 6.

As shown in FIG. 6, the p-type charge storage region 12 is provided along a wall surface of the inter-pixel separation region 15. Specifically, in the first embodiment, the charge storage region 12 is provided along the bottom surface of the lower portion on the second surface side of the pixel formation region 10a. That is, the charge storage region 12 is provided so that the first portion 12a in contact with the side surfaces of the well region 11, and the second portion 12b in contact with the bottom surface of the well region 11 surround the well region 11.

The p-type charge storage region 12 is formed with a p-type semiconductor region having a higher impurity concentration than that in the n-type well region 11, for example, and accumulates holes. The p-type charge storage region 12 is electrically connected to the p-type contact region 26 functioning as an anode, and enables bias adjustment. With this arrangement, the hole concentration in the p-type charge storage region 12 is enhanced, and pinning is strengthened. Thus, generation of dark current can be reduced, for example.

As shown in FIGS. 6 and 4, the p-type contact region 26 is provided on the upper surface (the first surface) of the pixel formation region 10a of the sensor substrate 10 so as to surround the outer periphery of the well region 11 and overlap the first portion 12a of the p-type charge storage region 12. That is, the p-type contact region has a square annular planar pattern that is a planar pattern in a plan view, and is in contact with and electrically connected to the first portion 12a of the charge storage region 12 over the entire circumference of the annular planar pattern. The contact region 26 lowers ohmic contact resistance with the contact electrode 32 described later, and functions as an anode. The p-type contact region 26 is formed with a p-type semiconductor region having a higher impurity concentration than those in the p-type first electrode region 19 and the p-type charge storage region 12.

As shown in FIGS. 6 and 4, the n-type contact region 27 is provided in an upper portion of the first portion 22a of the first electrode region 22. The n-type contact region 27 lowers ohmic contact resistance with the contact electrode 31 described later, and functions as a cathode. The n-type contact region 27 is formed with an n-type semiconductor region having a higher impurity concentration than that in the n-type second electrode region 22.

As shown in FIG. 6, the insulating portion 25 includes a recess 16 recessed from the upper surface (the first surface) of the pixel formation region 10a of the sensor substrate 10, and an insulating film 24 formed with silicon oxide as an insulator provided in the recess 16, for example. In this embodiment, the recess 16 is filled with the insulating film 24.

As shown in FIGS. 6 and 4, the insulating portion 25 surrounds the respective first portions 19a and 22a of the p-type first electrode region 19 and the second electrode region 22, and has a square annular planar pattern that is a planar pattern in a plan view.

As shown in FIG. 6, the wall surface (side surface) of the insulating portion 25 in contact with the second electrode region 22 is tilted with respect to the thickness direction of the sensor substrate 10. In other words, the wall surface of the insulating film 24 buried in the recess 16 in contact with the second electrode region 22, or, in other words, the wall surface of the island region defined by the recess 16 on the side of the second electrode region 22, or further, in other words, the wall surface of the sensor substrate 10 in the recess 16 on the side of the second electrode region 22, is tilted with respect to the Z direction orthogonal to the second surface of the sensor substrate 10.

As shown in FIG. 6, the p-type semiconductor region 18 has a thickness from the inner surface toward the inside of the recess 16 of the pixel formation region 10a of the sensor substrate 10, and is integrated with and electrically connected to the p-type semiconductor region 13. The n-type semiconductor region 21 has a thickness from the inner surface toward the inside of the recess 16 of the pixel formation region 10a of the sensor substrate 10, is integrated with and electrically connected to the n-type semiconductor region 14, and is p-n joined to the upper side of the p-type semiconductor region 18.

As shown in FIG. 5, the sensor-side wiring layer 30 includes contact electrodes 31 and 32, metal wiring lines 33 and 34, contact electrodes 35 and 36, and metal pads 37 and 38.

The contact electrode 31 electrically connects the n-type contact region 27 and the metal wiring line 33, and the contact electrode 32 electrically connects the p-type contact region 26 and the metal wiring line 34.

For example, as shown in FIG. 5, the metal wiring line 33 is formed to be wider than the avalanche multiplication region 23, so as to cover at least the avalanche multiplication region 23. The metal wiring line 33 then reflects light transmitted through the APD element 6, toward the APD element 6.

The metal wiring line 34 is formed so as to surround the outer periphery of the metal wiring line 33 and overlap the p-type contact region 26.

The contact electrode 35 electrically connects the metal wiring line 33 and the metal pad 37, and the contact electrode 36 electrically connects the metal wiring line 34 and the metal pad 38.

The metal pads 37 and 38 are electrically and mechanically connected to metal pads 47 and 48 provided in the logic-side wiring layer 40 by respective metal-to-metal joints.

As shown in FIG. 5, the logic-side wiring layer 40 includes electrode pads 41 and 42, an insulating layer 43, contact electrodes 44 and 45, and metal pads 47 and 48.

Each of the electrode pads 41 and 42 is connected to a logic circuit board that is not shown in the drawing, and the insulating layer 43 insulates the electrode pad 41 and the electrode pad 42 from each other.

The contact electrode 44 electrically connects the electrode pad 41 and the metal pad 47, and the contact electrode 45 electrically connects the electrode pad 42 and the metal pad 48.

The metal pad 37 is joined to the metal pad 47, and the metal pad 38 is joined to the metal pad 48.

With such a wiring structure, the electrode pad 41 is electrically connected to the n-type second electrode region 22 via the contact electrode 44, the metal pad 47, the metal pad 37, the contact electrode 35, the metal wiring line 33, the contact electrode 31, and the n-type contact region 27, for example. Thus, in the pixel 3, a large negative voltage to be applied to the n-type second electrode region 22 can be supplied from the logic circuit board to the electrode pad 41.

Also, the electrode pad 42 is electrically connected to the p-type first electrode region 19 via the contact electrode 45, the metal pad 48, the metal pad 38, the contact electrode 36, the metal wiring line 34, the contact electrode 32, and the n-type contact region 27. Accordingly, in the pixel 3, the anode of the APD element 6 electrically connected to the p-type charge storage region 12 is electrically connected to the electrode pad 42. Thus, bias adjustment can be performed on the p-type charge storage region 12 via the electrode pad 42.

As described above, in the pixel 3 of the distance image sensor 1 according to the first embodiment, the p-type first electrode region 19 and the n-type second electrode region 22 that form a p-n junction and have the avalanche multiplication region 23 formed at the interface portion of the p-n junction, and the p-type contact region 26 that functions as the anode are provided in an upper portion (on the first surface side) of the pixel formation region 10a of the sensor substrate 10. Further, the insulating portion 25 is provided between the p-type contact region 26 and the n-type second electrode region 22. Accordingly, with the distance image sensor 1 of the first embodiment, even if the p-type contact region 26 and the n-type second electrode region 22 come closer to each other as the pixels 3 are made smaller, or, in other words, even if the distance between the p-type contact region 26 and the n-type second electrode region 22 becomes shorter, the device withstand voltage between the p-type contact region 26 and the n-type second electrode region 22 can be maintained by the insulating portion 25. Thus, it is possible to make the pixel 3 smaller, while maintaining the device withstand voltage between the p-type contact region 26 and the n-type second electrode region 22. Further, as a result, the size of the distance image sensor 1 can be reduced.

As described above, the p-type first electrode region 19 and the n-type second electrode region 22 that have the avalanche multiplication region 23 formed at the p-n junction interface portion include: the first portions 19a and 22a in which the n-type second electrode region 22 (the n-type semiconductor region 14) and the p-type first electrode region 19 (the p-type semiconductor region 13) are arranged in this order in the depth direction from the upper surface (the first surface) of the pixel formation region 10a of the sensor substrate 10; and the second portions 19b and 22b that extend from the first portions 19a and 22a along a wall surface of the insulating portion 25 in the depth direction of the insulating portion 25. Accordingly, with the distance image sensor 1 of the first embodiment, even if the surface areas of the first portions 19a and 22a of the p-type first electrode region 19 and the n-type second electrode region 22 are reduced as the pixels 3 are made smaller, the surface areas of the second portions 19b and 22b can be increased. Thus, it is possible to make the pixel 3 smaller, while maintaining the surface area (the total area) of the avalanche multiplication region 23 formed at the p-n junction interface portion between the p-type first electrode region 19 and the n-type second electrode region 22. Further, as a result, the size of the distance image sensor 1 can be reduced. Furthermore, it is also possible to prevent a decrease in sensitivity or photon detection efficiency by increasing the amplification factor.

As described above, the wall surface of the insulating portion 25 in contact with the n-type second electrode region 22 is tilted with respect to the thickness direction (the Z direction) of the sensor substrate 10. Accordingly, with the distance image sensor 1 of the first embodiment, the surface areas of the second portions 19b and 22b of the p-type first electrode region 19 and the n-type second electrode region 22 can be made larger than those in a case where the wall surface of the insulating portion 25 in contact with the second electrode region 22 is parallel to the thickness direction (the Z direction) of the sensor substrate 10. Thus, it is possible to make the pixel 3 smaller, while maintaining a larger surface area (total area) for the avalanche multiplication region 23 formed in the p-n junction interface portion between the p-type first electrode region 19 and the n-type second electrode region 22.

<Method for Manufacturing the Distance Image Sensor>

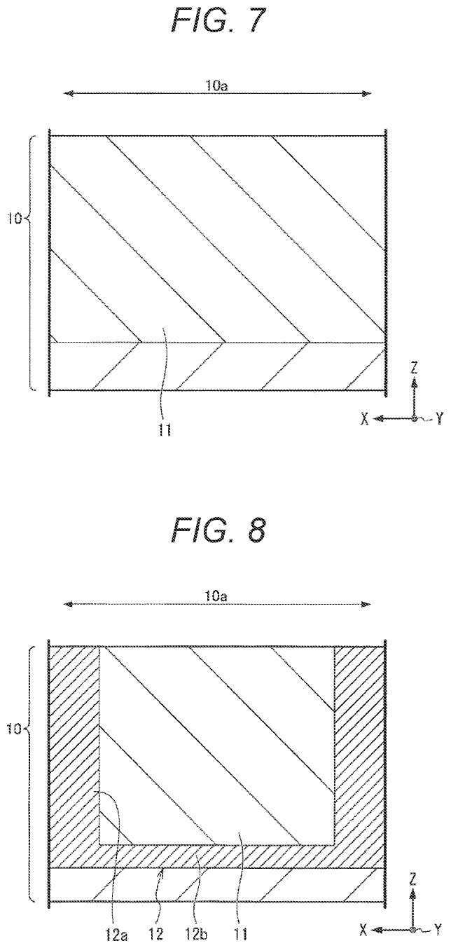

Next, an example method for manufacturing the distance image sensor according to the first embodiment is described, with reference to FIGS. 7 to 20.

First, the sensor substrate 10 formed with single-crystal silicon is prepared.

Next, as shown in FIG. 7, the n-type well region 11 is formed on the entire surface including the upper portion of the pixel formation region 10a of the sensor substrate 10. The well region 11 is formed as follows. For example, phosphorus (P) ions or arsenic (As) ions as the impurity ions exhibiting the n-type are implanted into the upper portion of the sensor substrate 10, and a heat treatment for activating the implanted impurity ions is then performed.

Next, as shown in FIG. 8, the p-type charge storage region 12 surrounding the side surfaces and the bottom surface of the well region 11 is formed for each pixel formation region 10a of the sensor substrate 10. The p-type charge storage region 12 is formed as follows. First, impurity ions for forming the first portion 12a in contact with the side surfaces of the well region 11 are selectively implanted into pixel formation region 10a of sensor substrate 10, and impurity ions for forming the second portion 12b in contact with the bottom portion of the well region 11 are selectively implanted into pixel formation region 10a of sensor substrate 10. A heat treatment for activating the impurity ions implanted into the pixel formation region 10a is then performed, so that the p-type charge storage region 12 is formed. As the impurity ions, boron (B) ions or boron difluoride (BF2) ions exhibiting the p-type are used, for example.

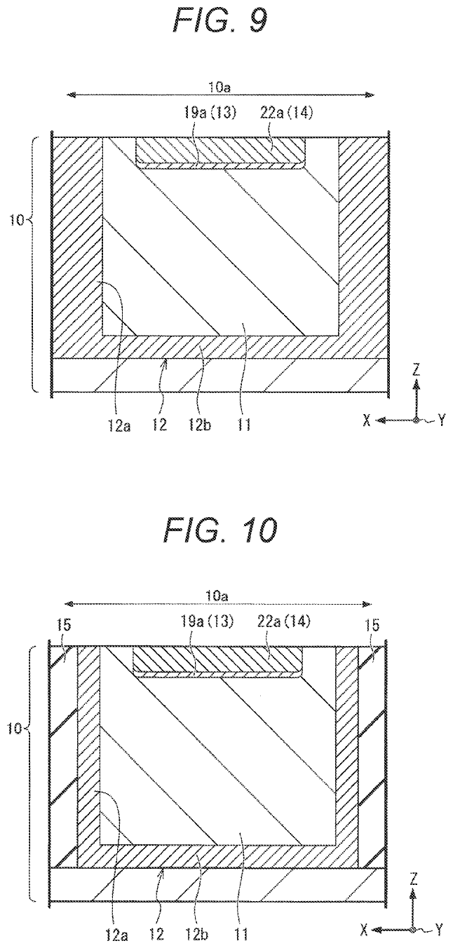

Next, as shown in FIG. 9, the p-type semiconductor region 13 is formed in the upper portion of the pixel formation region 10a of the sensor substrate 10 on the first surface side and in the upper portion of the well region 11 surrounded by the charge storage region 12, and the n-type semiconductor region 14 forming a p-n junction with the upper portion of the p-type semiconductor region 13 is formed. The p-type semiconductor region 13 and the n-type semiconductor region 14 are formed as follows. First, impurity ions exhibiting the p-type are selectively implanted into the upper portion of the well region 11, and impurity ions exhibiting the n-type are selectively implanted into the upper portion of the well region 11. A heat treatment for activating the impurity ions implanted in the well region 11 is then performed, so that the p-type semiconductor region 13 and the n-type semiconductor region 14 are formed. As the impurity ions exhibiting the p-type, B ions or BF2 ions are used, for example. As the impurity ions exhibiting the n-type, As ions or P ions are used, for example. The p-type impurity ions are implanted deeper than the impurity ions exhibiting the n-type. The p-type semiconductor region 13 forms the first portion 19a of the p-type first electrode region 19, and the n-type semiconductor region 14 forms the first portion 22a of the n-type second electrode region 22. The p-type semiconductor region 13 and the n-type semiconductor region 14 are arranged in this order in the depth direction from the upper surface (the first surface) of the pixel formation region 10a of the sensor substrate 10, and form a p-n junction.

Next, as shown in FIG. 10, the inter-pixel separation region 15 that electrically separates the pixel formation regions 10a from one another is formed in an upper portion of the sensor substrate 10. Each pixel formation region 10a is surrounded and defined by the inter-pixel separation region 15. The inter-pixel separation region 15 is formed as follows. Separation grooves extending in the depth direction from the first surface (the principal surface) of the sensor substrate 10 are formed by a known photolithography technique and an anisotropic dry etching technique, for example, and an insulating film is then selectively buried in the separation grooves. The burying of the insulating film is performed as follows. A silicon oxide film, for example, is formed on the entire first surface of the sensor substrate 10 including the insides of the separation grooves by a chemical vapor deposition (CVD) method, and the insulating film on the first surface of the sensor substrate 10 is then selectively removed by an etch-back method or a chemical mechanical polishing (CMP) method.

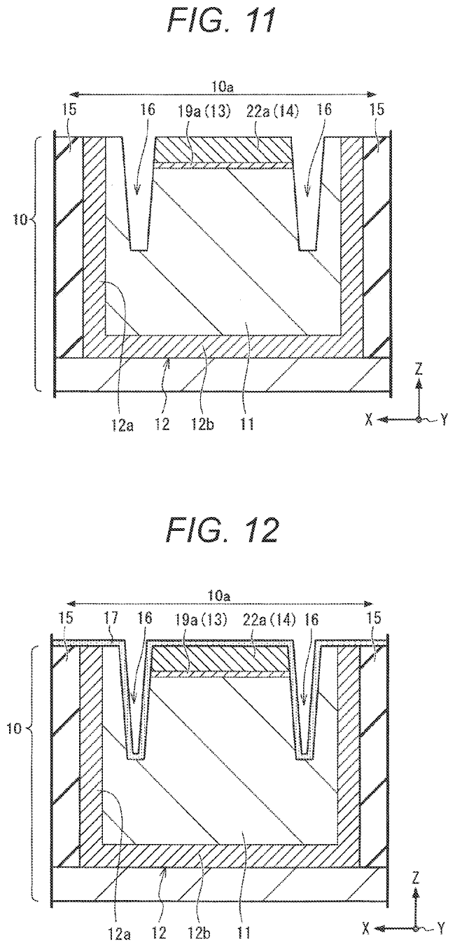

Next, as shown in FIG. 11, the recess 16 extending in the depth direction from the upper surface of the pixel formation region 10a of the sensor substrate 10 is formed. The recess 16 is formed by a known photolithography technique and a crystalline anisotropic etching technique that relies on the crystal axis of the sensor substrate, so that the wall surfaces in the recess 16 of the sensor substrate 10 can be tilted with respect to the thickness direction (the Z direction) of the sensor substrate 10. The recess 16 is formed with an annular planar pattern that is a square planar pattern in a plan view, so that the central portion of the pixel formation region 10a of the sensor substrate 10 becomes an island region.

Next, as shown in FIG. 12, a polycrystalline silicon film 17, for example, is formed as a first impurity ion introduction material on the entire first surface of the sensor substrate 10 including the inside of the recess 16 by a CVD method. Impurity ions exhibiting the p-type are implanted into the polycrystalline silicon film 17 during or after the deposition. As the impurity exhibiting the p-type, boron ions or boron difluoride ions are used, for example. The polycrystalline silicon film 17 is formed along inner surfaces including the wall surfaces and the bottom surface in the recess 16 of the sensor substrate 10.

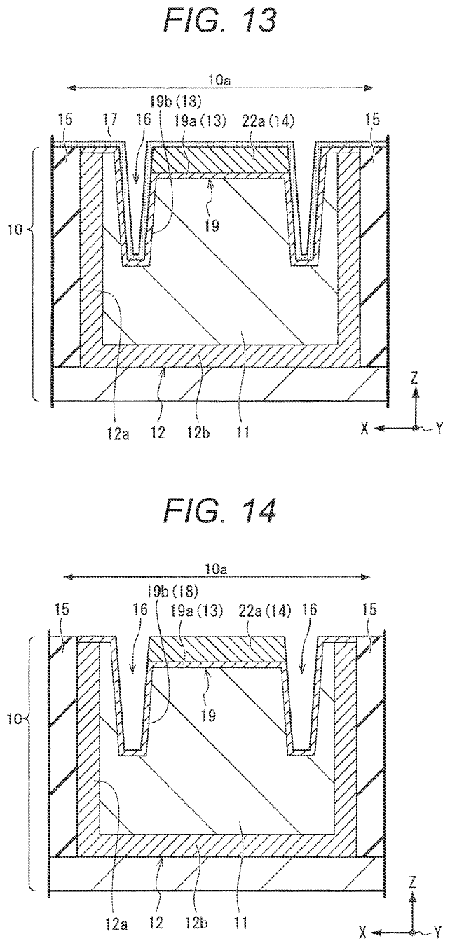

Next, a heat treatment for diffusing the impurity ions in the polycrystalline silicon film 17 from the inside of the recess 16 of the sensor substrate 10 into the entire sensor substrate 10 is performed to form the p-type semiconductor region 18 on the wall surfaces and the bottom surface in the recess 16 of the sensor substrate 10, and on the first surface of the sensor substrate 10, as shown in FIG. 13. The p-type semiconductor region 18 is integrally connected to the p-type semiconductor region 13, and forms the second portion 19b of the p-type first electrode region 19. Being formed by solid-phase diffusion (drive-in diffusion) of the impurity ions from the polycrystalline silicon film 17 into the sensor substrate 10, the p-type semiconductor region 18 is formed with a uniform thickness. The p-type semiconductor region 18 is formed along inner surfaces including the wall surfaces and the bottom surface in the recess 16 of the sensor substrate 10. Through this process, the p-type first electrode region 19 in which the first portion 19a formed with the p-type semiconductor region 13 and the second portion 19b formed with the p-type semiconductor region 18 are integrated is formed.

Next, as shown in FIG. 14, the polycrystalline silicon film 17 is removed.

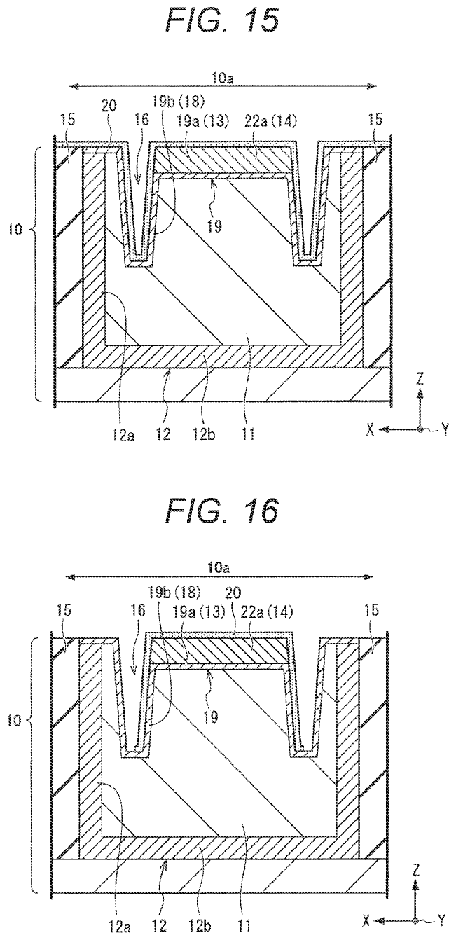

Next, as shown in FIG. 15, a polycrystalline silicon film 20, for example, is formed as a second impurity ion introduction material on the entire first surface of the sensor substrate 10 including the inside of the recess 16 by a CVD method. Impurity ions exhibiting the n-type (P ions or As ions, for example) are implanted into the polycrystalline silicon film 20 during or after the deposition. The polycrystalline silicon film 20 is formed along inner surfaces including the wall surfaces and the bottom surface in the recess 16 of the sensor substrate 10.

Next, as shown in FIG. 16, the polycrystalline silicon film 20 covering the wall surfaces and the upper surface on the side opposite to the n-type semiconductor region 14 in the recess 16 of the sensor substrate 10 is selectively removed by a known photolithography technique and a dry etching technique with high directivity. In this process, the polycrystalline silicon film 20 covers the wall surfaces on the side of the semiconductor region 14 in the recess 16 of the sensor substrate 10 and the semiconductor region 14, and terminates on the bottom surface in the recess 16.

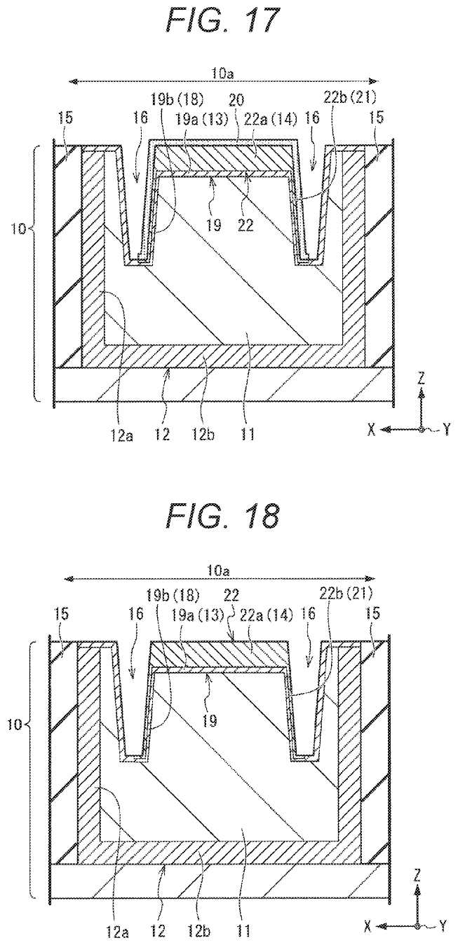

Next, a heat treatment for diffusing the impurity ions in the polycrystalline silicon film 20 from the inside of the recess 16 of the sensor substrate 10 into the sensor substrate 10 is performed, so that the n-type semiconductor region 21 is formed on the wall surfaces and the bottom surface on the side of the semiconductor region 14 in the recess 16 of the sensor substrate 10, as shown in FIG. 17. The n-type semiconductor region 21 is formed integrally with the n-type semiconductor region 14, and is p-n joined to the upper side of the p-type semiconductor region 18. The n-type semiconductor region 21 forms the second portion 22b of the n-type second electrode region 22. Being formed by solid-phase diffusion (drive-in diffusion) of the impurity ions from the polycrystalline silicon film 20 into the sensor substrate 10, the n-type semiconductor region 21 is formed with a uniform thickness. Through this process, the n-type second electrode region 22 is formed in which the first portion 22a formed with the n-type semiconductor region 14 and the second portion 22b formed with the n-type semiconductor region 21 are integrated, and the second portion 22b is p-n joined to the upper side of the second portion 19b of the p-type first electrode region 19.

Next, as shown in FIG. 18, the polycrystalline silicon film 20 is removed.

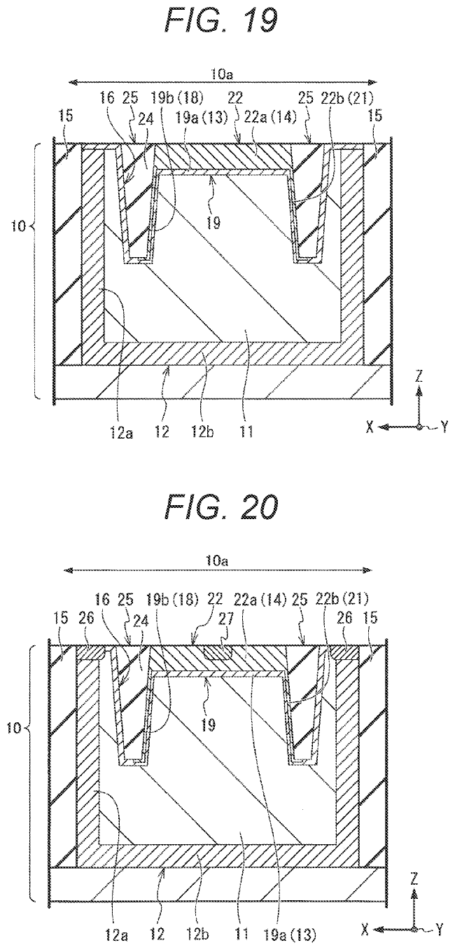

Next, as shown in FIG. 19, the insulating film 24 is buried as an insulator in the recess 16 of the sensor substrate 10. The burying of the insulating film 24 is performed as follows. An insulating film formed with a silicon oxide film, for example, is formed on the entire first surface of the sensor substrate 10 including the inside of the recess 16 by a CVD method, and the insulating film on the second surface of the sensor substrate 10 is then selectively removed by an etch-back method or a CMP method. Through this process, the insulating portion 25 including the recess 16 recessed from the upper surface of the sensor substrate 10, and the insulating film 24 as an insulator provided in the recess 16 is formed.

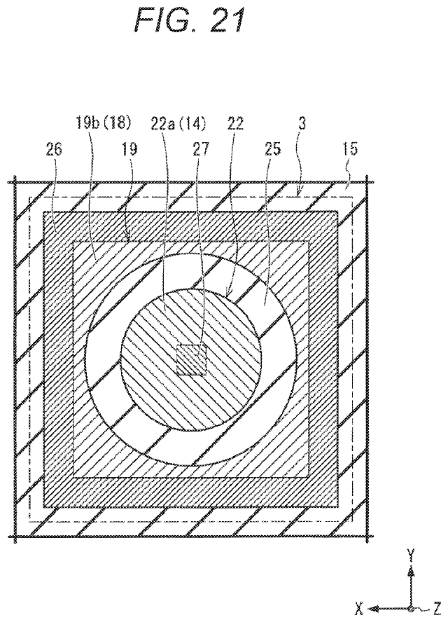

Next, as shown in FIG. 20, the p-type contact region 26 connected to the charge storage region 12 is formed on the charge storage region 12 and in an upper portion of the sensor substrate 10, and the n-type contact region 27 is formed in an upper portion of the first portion 22a (the n-type semiconductor region 14) of the n-type second electrode region 22 and in an upper portion of the sensor substrate 10. The p-type contact region 26 is formed by selectively implanting impurity ions (B ions or BF2 ions, for example) exhibiting the p-type into an upper portion between the inter-pixel separation region 15 of the sensor substrate 10 and the insulating portion 25, and then performing a heat treatment to activate the implanted impurity ions. Likewise, the n-type contact region 27 is also formed by selectively implanting impurity ions (P ions or As ions, for example) exhibiting the n-type into an upper portion of the n-type semiconductor region 14, and then performing a heat treatment to activate the implanted impurity ions. Through this process, the APD element 6 is formed in the pixel formation region 10a of the sensor substrate 10.

Next, the sensor-side wiring layer 30 is provided on the second surface of the sensor substrate 10, and the logic-side wiring layer 40 is provided on the logic circuit board. After that, the sensor-side wiring layer 30 and the logic-side wiring layer 40 are joined at the joining surface. Then, the second surface of the sensor substrate 10 is ground by CMP or the like until the inter-pixel separation region 15 is exposed, so that the thickness of the sensor substrate 10 is reduced. Further, the on-chip lens 50 is provided on the second surface of the sensor substrate 10. As a result, the distance image sensor 1 according to the first embodiment shown in FIGS. 1 to 6 is almost completed.

By the method for manufacturing the distance image sensor 1 according to the first embodiment, the insulating portion 25 is formed between the n-type second electrode region 22 and the p-type contact region 26. Thus, it is possible to manufacture the distance image sensor 1 having the pixels 3 made smaller in size, while maintaining the device withstand voltage between the n-type second electrode region 22 and the p-type contact region 26.

Also, by the method for manufacturing the distance image sensor 1 according to the first embodiment, the p-type first electrode region 19 and the n-type second electrode region 22 forming a p-n junction are formed in a two-dimensional plane parallel to the first surface of the sensor substrate 10, and in the depth direction of the sensor substrate 10. Thus, it is possible to manufacture the distance image sensor 1 having the pixels 3 made smaller in size, while maintaining the surface area (the total area) of the avalanche multiplication region 23 formed in the p-n junction interface portion between the p-type first electrode region 19 and the n-type second electrode region 22.

Furthermore, by the method for manufacturing the distance image sensor 1 according to the first embodiment, the respective second portions 19a and 22b of the p-type first electrode region 19 and the n-type second electrode region 22 forming a p-n junction are formed on wall surfaces in the recess 16 of the sensor substrate 10 by solid-phase diffusion from an impurity ion introduction material. Thus, each of the second portions 19b and 22b of the p-type first electrode region 19 and the n-type second electrode region 22 forming a p-n junction can be formed with a uniform thickness in the depth direction from a wall surface.

Note that, in the case described above in the first embodiment, the second portion 22b of the n-type second electrode region 22 is terminated immediately below the insulating portion 25. However, the present technology is not limited to the first embodiment. For example, the second portion 22b of the n-type second electrode region 22 may be terminated on the inner side of the lower portion of the insulating portion 25 (on the side of the n-type contact region 27), or may be terminated on the outer side the lower portion of the insulating portion 25 (on the side of the p-type contact region 26) as long as junction leakage does not occur at the interface with the p-type contact region 26. With an increase in the p-n junction area formed by the p-type first electrode region 19 and the n-type second electrode region 22, and the junction leakage between the n-type second electrode region 22 and the p-type contact region 26 being taken into consideration, the second portion 22b of the n-type second electrode region 22 is preferably terminated immediately below the lower portion of the insulating portion 25 as in the first embodiment described above.

Also, in the case described above in the first embodiment, the insulating film 24 is used as an insulator in the recess 16 of the insulating portion 25. However, the present technology is not limited to the insulating film 24. For example, the recess 16 may be filled with air, an inert gas, or the like as an insulator.

(Modifications)

Next, modifications of the insulating portion 25 are described.

In the case described above in the first embodiment, the planar pattern of the insulating portion 25 is formed as a square annular planar pattern. However, the present technology is not limited to the square annular pattern. For example, as a first modification, the planar pattern of the insulating portion 25 may be a circular annular planar pattern, as shown in FIG. 21.

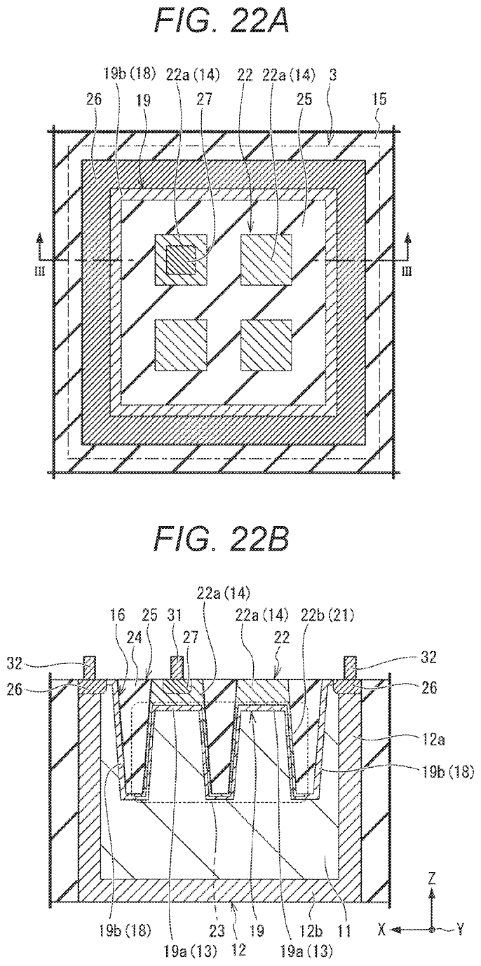

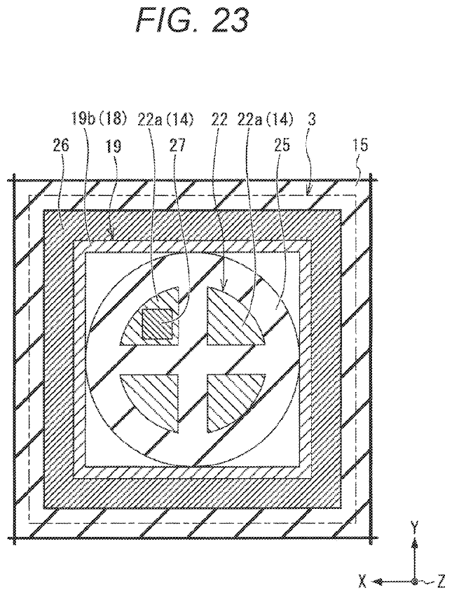

Alternatively, as a second modification, the planar pattern of the insulating portion 25 may be a composite planar pattern having a lattice-like pattern in a square annular pattern, as shown in FIGS. 22A and 22B. In the case of the composite planar pattern of the second modification, the junction area of the p-n junction formed by the p-type first electrode region 19 and the n-type second electrode region 22 can be made larger than that in the first embodiment described above. Thus, the surface area of the avalanche multiplication region 23 formed in the p-n junction interface portion between the p-type first electrode region 19 and the n-type second electrode region 22 can be increased.

Further, as a third modification, the planar pattern of the insulating portion 25 may be a composite planar pattern having a lattice-like pattern in a circular annular pattern, as shown in FIG. 23. In the composite pattern of the third modification, the junction area of the p-n junction formed by the p-type first electrode region 19 and the n-type second electrode region 22 can also be made larger than that in the first embodiment described above, as in the composite planar pattern of the second modification. Thus, the surface area of the avalanche multiplication region 23 formed in the p-n junction interface portion between the p-type first electrode region 19 and the n-type second electrode region 22 can be increased.

Here, in the cases of the second and third modifications, a plurality of first portions 22a (n-type semiconductor regions 14) of the n-type second electrode region 22 is interspersed while being surrounded by the insulating portion 25 in one pixel 3, but the first portions 22a are electrically connected to one another via the second portion 22b, as shown in FIGS. 22A, 22B, and 23. Therefore, the n-type contact region 27 is only required to be provided in at least one first portion 22a of the plurality of first portions 22a as shown in FIGS. 22A, 22B, and 23, or may be provided in all the first portions 22a though not illustrated in the drawings.

Next, a modification of the p-type contact region 26 is described.

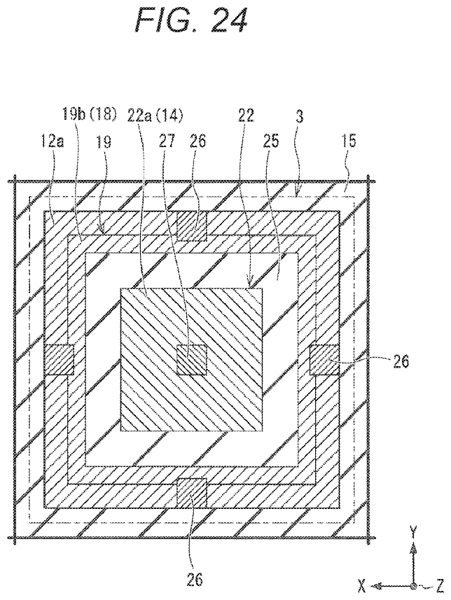

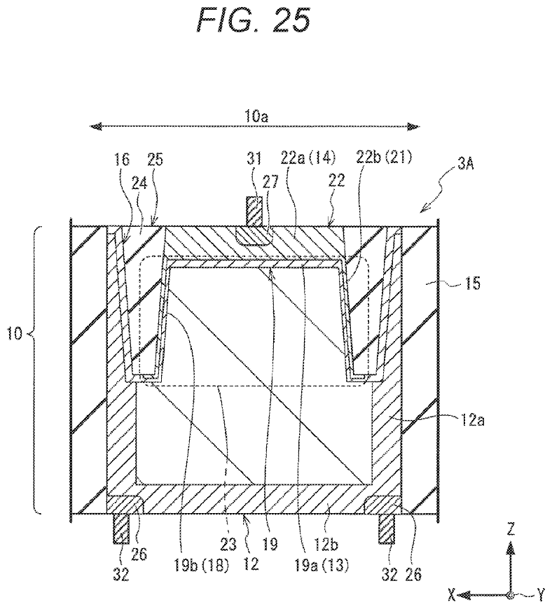

In the case described above in the first embodiment, the planar pattern of the p-type contact region 26 is formed as a square annular planar pattern. However, the present technology is not limited to the square annular planar pattern. For example, as a fourth modification, the planar pattern of the p-type contact region 26 may be a dot planar pattern in which a plurality of dots is interspersed around the insulating portion 25 in one pixel 3, as shown in FIG. 24. Alternatively, the planar pattern may be a one-dot planar pattern, though not illustrated in the drawings.

Here, in one pixel 3, the electric field concentrates in the vicinity of the p-type contact region 26 functioning as an anode. In view of this, to maintain the device withstand voltage between the p-type contact region 26 and the n-type second electrode region 22, the insulating portion 25 should be provided at least between the p-type contact region 26 and the n-type second electrode region 22. Therefore, in a case where the planar pattern of the p-type contact region 26 is a square annular planar pattern as in the first embodiment described above, the planar pattern of the insulating portion 25 is also preferably a square or circular annular planar pattern in compliance with the planar pattern of the p-type contact region 26. Alternatively, in a case where the planar pattern of the p-type contact region 26 is a dot planar pattern as in the fourth modification, the planar pattern of the insulating portion 25 is not necessarily an annular planar pattern. In short, it is sufficient that the insulating portion 25 is provided at least between the p-type contact region 26 and the n-type second electrode region 22 where the electric field concentrates. Therefore, the planar pattern of the insulating portion 25 in one pixel 3 may have any kind of shape, as long as junction leakage does not occur between the p-type contact region 26 and the n-type second electrode region 22. For example, other than an annular planar pattern and a dot planar pattern, a linear, C-shaped, or L-shaped planar pattern may be adopted.

### Second Embodiment

A distance image sensor according to a second embodiment of the present technology has a configuration substantially similar to that of the distance image sensor 1 according to the first embodiment described above, but has a different pixel configuration.

Specifically, a pixel 3 of the first embodiment has a structure in which the p-type first electrode region 19 and the n-type second electrode region 22, and the p-type contact region 26 are provided in an upper portion on the first surface side of the pixel formation region 10a of the sensor substrate 10. On the other hand, a pixel 3A of the second embodiment has a structure in which the p-type first electrode region 19 and the n-type second electrode region 22 are provided in an upper portion of the pixel formation region 10a of the sensor substrate 10, and the p-type contact region 26 is provided in a lower portion of the pixel formation region 10a of the sensor substrate 10. The other aspects of the configuration are similar to those of the first embodiment.

In the distance image sensor according to the second embodiment, it is also possible to make the pixel 3A smaller in size while maintaining the device withstand voltage between the p-type contact region 26 and the n-type second electrode region 22, as in the distance image sensor 1 according to the first embodiment described above. Further, it is possible to make the pixel 3A smaller, while maintaining the surface area (total area) of the avalanche multiplication region 23 formed in the p-n junction interface portion between the p-type first electrode region 19 and the n-type second electrode region 22.

(Example Configuration of an Electronic Apparatus)

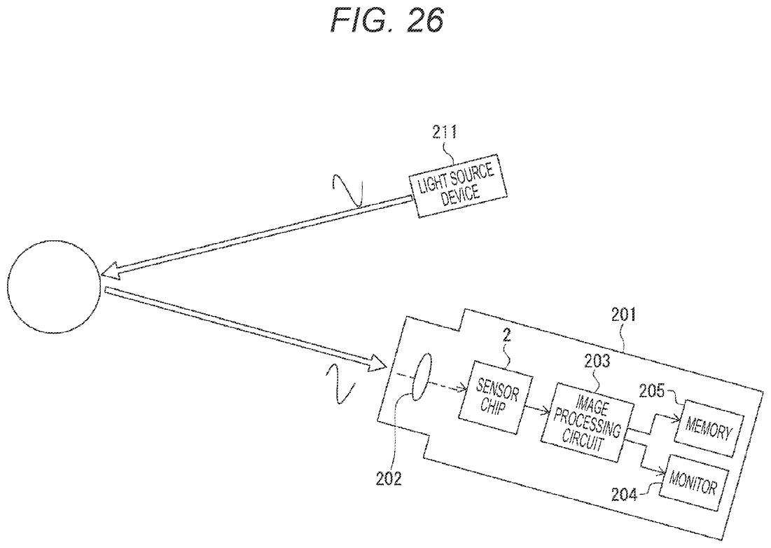

As shown in FIG. 26, a distance image device 201 as an electronic apparatus includes an optical system 202, a sensor chip 2, an image processing circuit 203, a monitor 204, and a memory 205. The distance image device 201 can acquire a distance image corresponding to the distance to the object, by receiving light (modulated light or pulsed light) that has been from a light source device 211 toward the object and been reflected by the surface of the object.

The optical system 202 includes one or a plurality of lenses, to guide image light (incident light) from the object to the sensor chip 2, and form an image on the light receiving surface (the sensor portion) of the sensor chip 2.

As the sensor chip 2, the sensor chip 2 of each of the above embodiments is adopted, and a distance signal indicating a distance obtained from a light reception signal (APD OUT) output from the sensor chip 2 is supplied to the image processing circuit 203.

The image processing circuit 203 performs image processing to construct a distance image on the basis of the distance signal supplied from the sensor chip 2, and the distance image (image data) obtained by the image processing is supplied to and displayed on the monitor 204, or is supplied to and stored (recorded) into the memory 205.

In the distance image device 201 designed as described above, the sensor chip 2 of the above embodiments is adopted. Thus, it is possible to calculate the distance to the object on the basis of only a light reception signal from a pixel 3 with high stability, and generate a highly accurate distance image. That is, the distance image device 201 can acquire a more accurate distance image.

(Examples of Use of an Image Sensor)

The above described sensor chip 2 (an image sensor) can be used in various cases where light, such as visible light, infrared light, ultraviolet light, or X-rays, is to be sensed, as listed below, for example.
Devices designed to take images for appreciation activities, such as digital cameras and portable devices with camera functions.
Devices for transportation use, such as vehicle-mounted sensors configured to take images of the front, the back, the surroundings, the inside, and the like of an automobile to perform safe driving such as an automatic stop and recognize the driver's condition and the like, surveillance cameras for monitoring running vehicles and roads, and ranging sensors for measuring distances between vehicles or the like.
Devices to be used in conjunction with home electric appliances, such as television sets, refrigerators, and air conditioners, to take images of gestures of users and operate the appliances in accordance with the gestures.
Devices for medical care use and health care use, such as endoscopes and devices for receiving infrared light for angiography.
Devices for security use, such as surveillance cameras for crime prevention and cameras for personal authentication.
Devices for beauty care use, such as skin measurement devices configured to image the skin and microscopes for imaging the scalp.
Devices for sporting use, such as action cameras and wearable cameras for sports and the like.
Devices for agricultural use such as cameras for monitoring conditions of fields and crops.

Note that the present technology may have the configurations described below.

(1)

A semiconductor device including

a pixel array unit in which a plurality of pixels each having an avalanche photodiode element is arranged in a matrix,

in which the avalanche photodiode element includes:

a first electrode region of a first conductivity type and a second electrode region of a second conductivity type, the first electrode region and the second electrode region being provided to form a p-n junction on a side of a first surface, the first surface and a second surface being located on opposite sides of a pixel formation region of a semiconductor layer, an avalanche multiplication region being formed at an interface portion of the p-n junction;

a contact region of the first conductivity type that is provided on the first surface side of the pixel formation region while being electrically connected to the first electrode region; and

an insulating portion that is provided between the contact region and the second electrode region.

(2)

The semiconductor device according to (1), in which

the insulating portion extends from the first surface of the pixel formation region toward the second surface side, and

the first electrode region and the second electrode region each include:

a first portion that is disposed from the first surface side toward the second surface side of the pixel formation region; and

a second portion that extends from the first portion along the insulating portion.

(3)

The semiconductor device according to (2), in which the second portion of the first electrode region reaches the contact region from the first portion of the first electrode region beyond the second surface side of the pixel formation region of the insulating portion.

(4)

The semiconductor device according to (2), in which the second portion of the second electrode region terminates on the second surface side of the pixel formation region of the insulating portion.

(5)

The semiconductor device according to any one of (1) to (4), in which the second electrode region forms a p-n junction with the first electrode region at an upper side of the first electrode region.

(6)

The semiconductor device according to any one of (1) to (5), in which a side wall of the insulating portion in contact with the second electrode region is tilted with respect to a thickness direction of the semiconductor layer.

(7)

The semiconductor device according to any one of (1) to (6), in which the insulating portion includes: a recess that is recessed from the first surface of the pixel formation region; and an insulator that is provided in the recess.

(8)

The semiconductor device according to any one of (1) to (7), in which the insulating portion has an annular shape in a plan view.

(9)

The semiconductor device according to any one of (1) to (7), in which the insulating portion has a lattice-like shape in a plan view.

(10)

The semiconductor device according to any one of (1) to (9), in which the contact region has an annular shape in a plan view.

(11)

The semiconductor device according to any one of (1) to (9), in which the contact region is interspersed around the pixel formation region.

(12)

The semiconductor device according to any one of (1) to (11), in which the pixel formation region is defined by an inter-pixel separation region extending in a depth direction from the first surface of the semiconductor layer.

(13)

The semiconductor device according to any one of (1) to (12), further including a charge storage region of the first conductivity type that extends along the inter-pixel separation region, and is electrically connected to the contact region.

(14)

A semiconductor device manufacturing method including:

the step of forming a first electrode region of a first conductivity type and a second electrode region of a second conductivity type forming a p-n junction with the first electrode region, on a first surface side of a semiconductor layer;

the step of forming a contact region of the first conductivity type that is electrically connected to the first electrode region, on the first surface side of the semiconductor layer; and

the step of forming an insulating portion between the second electrode region and the contact region.

(15)

An electronic apparatus including:

the semiconductor device according to any one of (1) to (13); and

an optical system that forms an image of image light from an object on the second surface of the pixel formation region.

The scope of the present technology is not limited to the illustrated and described exemplary embodiments, but also includes all embodiments that provide effects equivalent to those for which the present technology is intended. Further, the scope of the present technology is not limited to combinations of the features of the inventions disclosed in the claims, but may be defined by any desired combinations of specific features among all the disclosed features.

### REFERENCE SIGNS LIST

1 Distance image sensor (semiconductor device)
2 Sensor chip
2A Pixel array unit
2B Peripheral region
2C Pad region
3 Pixel
4 Electrode pad
5 Bias voltage application unit
6 APD element
7 Quenching resistive element
8 Inverter
10 Sensor substrate (semiconductor layer)
11 n-type well region
12 p-type charge storage region
12a First portion
12b Second portion
13 p-type semiconductor region (first semiconductor region)
14 n-type semiconductor region (second semiconductor region)
15 Inter-pixel separation region
16 Recess
17 Polycrystalline silicon film (first impurity diffusion material)
18 p-type semiconductor region (third semiconductor region)
19 p-type first electrode region
19a First portion
19b Second portion
20 Polycrystalline silicon film (second impurity diffusion material)
21 n-type semiconductor region (third semiconductor region)
22 n-type second electrode region
22a First portion
22b Second portion
23 Avalanche multiplication region
24 Insulating film (insulator)
25 Insulating portion
26 p-type contact region
27 n-type contact region
30 Sensor-side wiring layer
31, 32 Contact electrode
33, 34 Metal wiring line
35, 36 Contact electrode
37, 38 Metal pad
40 Logic-side wiring layer
41, 42 Electrode pad
43 Insulating layer
44, 45 Contact electrode
47, 48 Metal pad
50 On-chip lens

What is claimed is:

1. A semiconductor device comprising
a pixel array unit in which a plurality of pixels each having an avalanche photodiode element is arranged in a matrix,
wherein the avalanche photodiode element includes:
a first electrode region of a first conductivity type and a second electrode region of a second conductivity type, the first electrode region and the second electrode region being provided to form a p-n junction on a side of a first surface, the first surface and a second surface being located on opposite sides of a pixel formation region of a semiconductor layer, an avalanche multiplication region being formed at an interface portion of the p-n junction;
a contact region of the first conductivity type that is provided on the first surface side of the pixel formation region while being electrically connected to the first electrode region; and
an insulating portion that is provided between the contact region and the second electrode region.

2. The semiconductor device according to claim 1, wherein
the insulating portion extends from the first surface side of the pixel formation region toward the second surface side, and
the first electrode region and the second electrode region each include:
a first portion that is disposed from the first surface side toward the second surface side of the pixel formation region; and
a second portion that extends from the first portion along the insulating portion.

3. The semiconductor device according to claim 2, wherein the second portion of the first electrode region reaches the contact region from the first portion of the first electrode region beyond the second surface side of the pixel formation region of the insulating portion.

4. The semiconductor device according to claim 2, wherein the second portion of the second electrode region terminates on the second surface side of the pixel formation region of the insulating portion.

5. The semiconductor device according to claim 1, wherein the second electrode region forms a p-n junction with the first electrode region at an upper side of the first electrode region.

6. The semiconductor device according to claim 1, wherein a side wall of the insulating portion in contact with the second electrode region is tilted with respect to a thickness direction of the semiconductor layer.

7. The semiconductor device according to claim 1, wherein the insulating portion includes: a recess that is recessed from the first surface of the pixel formation region; and an insulator that is provided in the recess.

8. The semiconductor device according to claim 1, wherein the insulating portion has an annular shape in a plan view.

9. The semiconductor device according to claim 1, wherein the insulating portion has a lattice-like shape in a plan view.

10. The semiconductor device according to claim 1, wherein the contact region has an annular shape in a plan view.

11. The semiconductor device according to claim 1, wherein the contact region is interspersed around the pixel formation region.

12. The semiconductor device according to claim 1, wherein the pixel formation region is defined by an inter-pixel separation region extending in a depth direction from the first surface of the semiconductor layer.

13. The semiconductor device according to claim 12, further comprising a charge storage region of the first conductivity type that extends along the inter-pixel separation region, and is electrically connected to the contact region.

14. A semiconductor device manufacturing method comprising:
the step of forming a first electrode region of a first conductivity type and a second electrode region of a second conductivity type forming a p-n junction with the first electrode region, on a first surface side of a semiconductor layer;
the step of forming a contact region of the first conductivity type that is electrically connected to the first electrode region, on the first surface side of the semiconductor layer; and
the step of forming an insulating portion between the second electrode region and the contact region.

15. An electronic apparatus comprising:
a semiconductor device that includes a pixel array unit in which a plurality of pixels each having an avalanche photodiode element is arranged in a matrix, the avalanche photodiode element including: a first electrode region of a first conductivity type and a second electrode region of a second conductivity type, the first electrode region and the second electrode region being provided to form a p-n junction on a side of a first surface, the first surface and a second surface being located on opposite sides of a pixel formation region of a semiconductor layer, an avalanche multiplication region being formed at an interface portion of the p-n junction; a contact region of the first conductivity type that is provided on the first surface side of the pixel formation region while being electrically connected to the first electrode region; and an insulating portion that is provided between the contact region and the second electrode region; and
an optical system that forms an image of image light from an object on the second surface of the pixel formation region.
